(19) United States
(12) Patent Application Publication
(10) Pub. No.: US 2008/0073655 A1
(43) Pub. Date: Mar. 27, 2008

(54) Optoelectronic semiconductor chip

(75) Inventors: Tony Albrecht, Bad Abbach (DE); Georg Bruderl, Burglengenfeld (DE); Volker Harle, Laaber (DE); Lutz Hoppel, Alteglofsheim (DE); Martin Strassburg, Tegernheim (DE)

Correspondence Address: COHEN PONTANI LIEBERMAN & PAVANE LLP;Suite 1210, 551 Fifth Avenue, New York, NY, 10176, US

(73) Assignee: OSRAM Opto Semiconductors GmbH, Regensburg (DE)

(21) Appl. No.: 11/901,666

(22) Filed: Sep. 17, 2007

(30) Foreign Application Priority Data
Sep. 15, 2006 (DE) 10 2006 043 400.5

(51) Int. Cl. H01L 31/0236; H01L 33/00

(52) U.S. Cl. 257/79; 257/466; 257/E33.001; 257/E31.13

(57) ABSTRACT

An optoelectronic semiconductor chip comprises a growth substrate with a structured growth area (2) having a multiplicity of elevations (4) and depressions (3), and an active layer sequence (5) applied to the growth area (2).

### RELATED APPLICATION

This patent application claims the priority of German patent application 10 2006 043 400.5 filed Sep. 15, 2006, the disclosure content of which is hereby incorporated by reference.

### FIELD OF THE INVENTION

The present invention is directed to an optoelectronic semiconductor chip

### BACKGROUND OF THE INVENTION

The document US 2003/0085409A1 describes an optoelectronic semiconductor chip.

### SUMMARY OF THE INVENTION

One object of the invention is to provide an optoelectronic semiconductor chip which can be operated particularly efficiently.

A further object of the invention is to provide an optoelectronic semiconductor chip which can be produced particularly cost-effectively.

These and other objects are attained in accordance with one aspect of the present invention directed to an optoelectronic semiconductor chip comprising a growth substrate with a structured growth area having a multiplicity of elevations and depressions, and an active layer sequence applied to the growth area.

In accordance with at least one embodiment of the optoelectronic semiconductor chip, the semiconductor chip comprises a growth substrate. The growth substrate is for example a body which contains a semiconductor material or consists of a semiconductor material. The growth substrate has at least one growth area. The growth area is provided for epitaxially depositing a semiconductor material and/or a metallic material on it. The growth area is formed for example by a main area of the growth substrate.

In accordance with at least one embodiment of the optoelectronic semiconductor chip, the growth area of the growth substrate is structured. This means for example that the growth area is not formed in planar or smooth fashion, rather the growth area has three-dimensional structures. Preferably, the growth area has a multiplicity of elevations and/or depressions. On account of the structuring, the growth area has a rough surface, the surface area of which is increased compared with the surface area of a smooth surface.

In accordance with at least one embodiment of the optoelectronic semiconductor-chip, an active layer sequence is applied to the structured growth area of the substrate. The active layer sequence comprises for example a plurality of layers, at least one layer being provided for detecting radiation or generating radiation during the operation of the optoelectronic semiconductor chip. By way of example, the active layer sequence comprises a pn junction, a double heterostructure or a quantum well structure.

The active layer sequence is preferably deposited epitaxially onto the growth area of the growth substrate. In this case, the active layer sequence can adjoin the structured growth area—that is to say, for example, the elevations and/or depressions—in a form-fitting manner at least in places. The profile of the structured growth area is preferably reproduced conformally—that is to say in an isogonal manner—in the active layer sequence at least in places. This means, in particular, that the active layer sequence does not simply overgrow the structuring of the growth area in such a way that a smooth and/or planar outermost layer of the active layer sequence remote from the growth substrate arises. Rather in terms of its morphology, the active layer sequence follows the structure of the growth area at least in places.

In accordance with at least one embodiment of the optoelectronic semiconductor chip, the semiconductor chip comprises a growth substrate with a structured growth area having a multiplicity of elevations and/or depressions. Furthermore, the optoelectronic semiconductor chip comprises an active layer sequence applied to the growth area.

In this case, an optoelectronic semiconductor chip described here is based on the following idea, inter alia: optoelectronic semiconductor chips produced in a conventional manner often comprise an active layer sequence applied to a smooth, planar growth area of a growth substrate. The active area of the active layer sequence of the semiconductor chip—that is to say, for example, that area of the active layer sequence which is provided for generating radiation or detecting radiation—is then at most as large as the growth area. On account of the structuring of the growth area described here, the growth area is enlarged. Since the active layer sequence is applied to this structured, enlarged growth area, the surface area of the active layer sequence is also enlarged compared with the surface area of a smooth, planar active layer sequence. The active layer sequence thus has a larger area of content than the lateral cross-sectional area of the growth substrate. In this case, the lateral cross-sectional area of the growth substrate is understood to mean the surface area of the growth area of the growth substrate prior to the structuring, that is to say the surface area of a smooth, planar growth area.

The fact that the surface area of the active layer sequence is enlarged means that, with the chip size remaining the same, more electromagnetic radiation can be generated or detected by the active layer sequence. If the optoelectronic semiconductor chip is a light emitting diode chip, for example, then the enlargement of the surface area of the active layer sequence as described here leads to an increased luminance with the lateral cross-sectional area remaining the same, and hence overall to a more efficient light emitting diode chip.

Preferably, the semiconductor chip also has a rough surface remote from the growth substrate, said rough surface resulting from the structured growth area of the growth substrate. If the optoelectronic semiconductor chip is a light emitting diode chip, for example, then said rough surface preferably forms a radiation exit area of the semiconductor chip. On account of the roughness of the radiation exit area, the probability of total reflection in the course of the radiation exit is reduced, and the efficiency of the semiconductor chip is also improved as a result.

In accordance with at least one embodiment of the optoelectronic semiconductor chip, the semiconductor chip having the structured growth area generates or detects more electromagnetic radiation during operation than a corresponding semiconductor chip having a smooth growth area. In this case, a corresponding semiconductor chip is understood to mean a semiconductor chip which, apart from the smooth growth area, is constructed like the semiconductor chip having the structured growth area. In particular, the corresponding semiconductor chip also has the same lateral cross-sectional area as the semiconductor chip having the structured growth area.

In accordance with at least one embodiment of the optoelectronic semiconductor chip, the semiconductor chip having the structured growth area generates or detects electromagnetic radiation having a higher radiation density during operation than a corresponding semiconductor chip having a smooth growth area which has the same lateral cross-sectional area as the semiconductor chip having the structured growth area. In this case, a corresponding semiconductor chip is understood to mean a semiconductor chip which, apart from the smooth growth area, is constructed like the semiconductor chip having the structured growth area.

In accordance with at least one embodiment of the optoelectronic semiconductor chip, electromagnetic radiation is generated or detected during the operation of the optoelectronic semiconductor chip over the entire area of the active layer sequence. That is to say that the generation or detection of electromagnetic radiation is not restricted to specific regions of the active layer sequence, such as, for example, regions of the active layer sequence which are arranged in depressions of the structured growth area. Rather, all the regions of the active layer sequence in at least this embodiment are provided for generating radiation or detecting radiation.

In accordance with at least one embodiment of the optoelectronic semiconductor chip, the growth area of the growth substrate is structured regularly. That is to say that the structures on the growth area are produced in a predetermined manner according to specific rules. By way of example, the structures are produced by means of a lithographic process with subsequent isotropic etching. In this way, elevations and/or depressions having structure sizes that are substantially identical can be produced, for example, over the entire growth area. The phrase “substantially identical” means, for example, that the structure sizes of the individual structures vary at most 10% around an average value of the respective structure size. In this case, structure sizes of elevations are for example the lateral extent of the elevation, the height of the elevation and/or the sidewall angle of the elevation. Structure sizes of a depression are for example the lateral extent of the depression, the depth of the depression and/or the sidewall angle of the depression.

In accordance with at least one embodiment of the optoelectronic semiconductor chip, the growth area is structured regularly in such a way that the elevations and/or depressions are arranged periodically. The elevations and/or depressions then form for example a type of wave pattern on the growth area. The distance between two adjacent elevations along a predetermined direction on the growth area is then a substantially constant value—the period length. In this case, substantially constant means once again that the period length fluctuates by at most 10% around its average value.

In this case, the average distance between two elevations on the growth area is preferably at most 2 μm, particularly preferably at most 1 μm.

In accordance with at least one embodiment of the optoelectronic semiconductor chip, the growth area is structured irregularly. That is to say that the growth area is structured in a random or approximately random manner.

An irregular structuring of the growth area can be produced for example by anisotropically etching a smooth growth area of the growth substrate. A crystallographically roughened structure is produced in this way. Elevations and/or depressions are then formed as irregular structures on the growth area. This means that the elevations and/or depressions have nonuniform structure sizes and/or distances. The average distance between two elevations is preferably at most 500 nm in this case. Elevations and/or depressions having nonuniform structure sizes can be arranged regularly or irregularly in this case.

In accordance with at least one embodiment of the optoelectronic semiconductor chip, in the case of an irregular structuring of the growth area, the surface area of the active layer sequence is greater than the surface area of the lateral cross-sectional area of the growth substrate. This can be achieved for example by an active layer sequence being deposited epitaxially onto the irregularly structured growth area, said active layer sequence following the profile of the structured growth area. That is to say, in other words, the active layer sequence nestles against the structured growth area and thereby has a larger area content than the cross-sectional area of the growth substrate. Besides the advantage of the effectively enlarged area of the active layer sequence, the roughened structure of the growth area also brings about an improved coupling out of light generated in the active layer sequence, for example, since the probability of total reflection of the light at one of the outer areas of the optoelectronic semiconductor chip is reduced on account of the rough structure of the active layer sequence. Overall, the structuring of the growth area of the growth substrate enlarges the surface of the growth substrate and hence the surface area of the growth area. The surface area of the active layer sequence is also enlarged as a result of the enlargement of the growth area. In this way, more radiation-generating and/or radiation-detecting area of the active layer sequence is available compared with a growth substrate having a smooth, planar growth area. In this way, a particularly efficient optoelectronic semiconductor chip is produced which, in addition, is particularly cost-effective since the chip area can be reduced compared with conventional optoelectronic semiconductor chips without the luminous efficiency being impaired.

In accordance with at least one embodiment of the optoelectronic semiconductor chip, the active layer sequence has a substantially constant thickness. In this case, a substantially constant thickness means that the thickness of the active layer sequence fluctuates by at most 10% around an average thickness of the layer sequence. In this case, the average thickness of the active layer sequence is preferably at most 20 μm.

In accordance with at least one embodiment of the optoelectronic semiconductor chip, the structuring of the growth area extends over the entire growth area. This means that the entire area of the growth substrate that is covered by the active layer sequence is structured and has for example elevations and/or depressions.

In accordance with at least one embodiment, the growth substrate contains GaN or consists of GaN. In particular, it is then possible for the growth substrate to contain n-doped GaN or to consist of n-doped GaN. The active layer sequence is then preferably based on nitride compound semiconductors. In this case, the n-doped gallium nitride growth substrate can serve as n-doped contact layer of the active layer sequence.

In accordance with at least one embodiment, the growth substrate contains InGaN or consists of InGaN.

In accordance with at least one embodiment, the growth substrate contains AlGaN or consists of AlGaN.

In accordance with at least one embodiment, the growth substrate contains InAlGaN or consists of InAlGaN.

In accordance with at least one embodiment, the growth substrate contains or the growth substrate consists of a ternary or a quaternary III-N compound such as, for example, InGaN, AlGaN or InAlGaN.

In accordance with at least one embodiment, the growth substrate contains SiC or consists of SiC.

In accordance with at least one embodiment, the growth substrate contains sapphire or consists of sapphire.

In accordance with at least one embodiment, the growth substrate contains or the growth substrate consists of an oxidic semiconductor such as ZnO, for example.

In accordance with at least one embodiment of the optoelectronic semiconductor chip, the active layer sequence is based on nitride compound semiconductors. In the present context, “based on nitride compound semiconductors” means that the active layer sequence or at least one layer thereof comprises a nitride III/V compound semiconductor material, preferably AlₙGaₘIn₁₋ₙ₋ₘN, where 0≦n≦1, 0≦m≦1 and n+m≦1. In this case, said material need not necessarily have a mathematically exact composition according to the above formula. Rather, it can have one or a plurality of dopants or additional constituents which do not substantially change the characteristic physical properties of the AlₙGaₘIn₁₋ₙ₋ₘN material. For the sake of simplicity, however, the above formula only comprises the essential constituents of the crystal lattice—Al, Ga, In, N—, even though these can be replaced in part by small quantities of further substances.

In accordance with at least one embodiment of the optoelectronic semiconductor chip, the active layer sequence is based on phosphide compound semiconductors. In the present context, “based on phosphide compound semiconductors” means that the active layer sequence or at least one layer thereof comprises preferably AlₙGaₘIn₁₋ₙ₋ₘP, where 0≦n≦1, 0≦m≦1 and n+m≦1. In this case, said material need not necessarily have a mathematically exact composition according to the above formula. Rather, it can have one or a plurality of dopants or additional constituents which do not substantially change the physical properties of the material. For the sake of simplicity, however, the above formula only comprises the essential constituents of the crystal lattice (Al, Ga, In, P), even though these can be replaced in part by small quantities of further substances.

In accordance with at least one embodiment of the optoelectronic semiconductor chip, the active layer sequence is based on arsenide compound semiconductors. In the present context, “based on arsenide compound semiconductors” means that the active layer sequence or at least one layer thereof comprises preferably AlₙGaₘIn₁₋ₙ₋ₘAs, where 0≦n≦1, 0≦m≦1 and n+m≦1. In this case, said material need not necessarily have a mathematically exact composition according to the above formula. Rather, it can have one or a plurality of dopants or additional constituents which do not substantially change the physical properties of the material. For the sake of simplicity, however, the above formula only comprises the essential constituents of the crystal lattice (Al, Ga, In, As), even though these can be replaced in part by small quantities of further substances.

In accordance with at least one embodiment of the optoelectronic semiconductor chip, the elevations and/or depressions of the growth area of the growth substrate are structured by means of at least one etching process. In this case, an isotropic etching process can be used in which regular structures are subsequently etched into the growth substrate after a lithographic method. Furthermore, it is possible for the growth area to be roughened by means of an anisotropic etching method. This anisotropic etching method is particularly well suited to producing irregular, random structures on the growth area of the growth substrate.

In accordance with at least one embodiment, the elevations and/or depressions are produced epitaxially. That is to say that a material is deposited epitaxially onto a planar or stepped growth area of the growth substrate. Elevations are grown on the growth area for example by means of self-assembled growth or by means of a mask technique. In this way, both regular and irregular structures can be produced on the growth area.

### BRIEF DESCRIPTION OF THE DRAWINGS

FIGS. 1A, 1B and 1C are schematic sectional views illustrating a first exemplary embodiment of a method for producing an optoelectronic semiconductor chip.

FIGS. 2A and 2B are schematic sectional views illustrating a second exemplary embodiment of a method for producing an optoelectronic semiconductor chip.

### DETAILED DESCRIPTION OF THE DRAWINGS

In the exemplary embodiments and figures, identical or identically acting component parts are in each case provided with the same reference symbols. The elements illustrated should not be regarded as true to scale, rather individual elements may be illustrated with an exaggerated size in order to afford a better understanding.

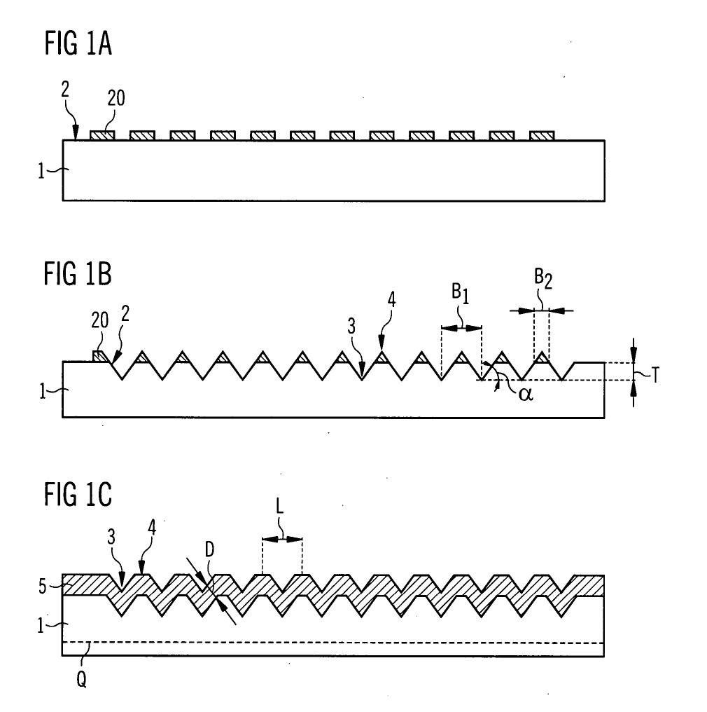

A first exemplary embodiment of a method for producing an optoelectronic semiconductor chip described here is described on the basis of schematic sectional illustrations in FIGS. 1A, 1B and 1C. FIG. 1C shows an optoelectronic semiconductor chip described here in accordance with a first exemplary embodiment in a schematic sectional illustration.

FIG. 1A shows a growth substrate 1 with a planar, smooth growth area 2. The growth substrate 1 is, for example, an n-doped GaN growth substrate. A patterned photoresist layer 20 is applied to the growth substrate. The photoresist layer 20 is patterned, for example, by means of a lithographic method.

The growth substrate 1 is etched isotropically in a next method step, which is described in conjunction with FIG. 1B. The regions of the growth area 2 of the growth substrate 1 which are not covered by the patterned photoresist layer 20 are etched. Depressions 3 and elevations 4 arise on the growth area 2 in this way.

By means of the isotropic etching process, periodic structures are structured into the growth area 2 of the growth substrate 1.

In this case, the average distance L between two elevations 4 of the growth substrate 1 is at most 20 μm, preferably at most 2 μm, particularly preferably at most 1 μm.

In this case, the average width B1 of the base of one of the elevations 4 of the growth substrate 1 is at most 20 μm, preferably at most 2 μm, particularly preferably at most 1 μm. Preferably, the width B1 of the base of one of the elevations 4 is identical or approximately identical to the average distance L between two elevations 4.

In this case, the average depth T of one of the elevations 4 of the growth substrate 1 is at most 20 μm, preferably at most 2 μm, particularly preferably at most 1 μm.

In this case, the average width B2 at the tip of one of the elevations 4 of the growth substrate 1 is at most 5 μm, preferably at most 1 μm, particularly preferably at most 0.2 μm.

The sidewall angle α of an elevation 4 results correspondingly from these values.

The remaining photoresist layer 20 is subsequently stripped from the growth substrate 1.

FIG. 1C shows a first exemplary embodiment of an optoelectronic semiconductor chip described here. The optoelectronic semiconductor chip is for example a light emitting diode chip, a laser diode chip or a photodetector chip.

In this case, an active layer sequence 5 is deposited epitaxially onto the structured growth area 2 of the growth substrate 1 having depressions 3 and elevations 4.

The course of the active layer sequence 5 follows the profile of the growth area 2. Thus, the depressions of the active layer sequence 5 are situated at depressions 3 of the growth substrate 1 and elevations of the active layer sequence 5 are situated at elevations 4 of the growth substrate 1.

The active layer sequence 5 is preferably a layer having a uniform thickness. The thickness D of the active layer 5 is preferably 6 μm, at least 10 nm and at most 20 μm.

The dashed line Q indicates the lateral cross-sectional area of the semiconductor chip.

The active layer sequence 5 comprises at least one layer provided for generating radiation and/or detecting radiation. The active layer sequence preferably comprises a pn junction, a double heterostructure or a quantum well structure.

In the context of the present disclosure, the designation “quantum well structure” encompasses in particular any structure in which charge carriers can experience a quantization of their energy states as a result of confinement. In particular, the designation “quantum well structure” does not comprise any indication about the dimensionality of the quantization. It therefore encompasses, inter alia, quantum wells, quantum wires and quantum dots and any combination of these structures.

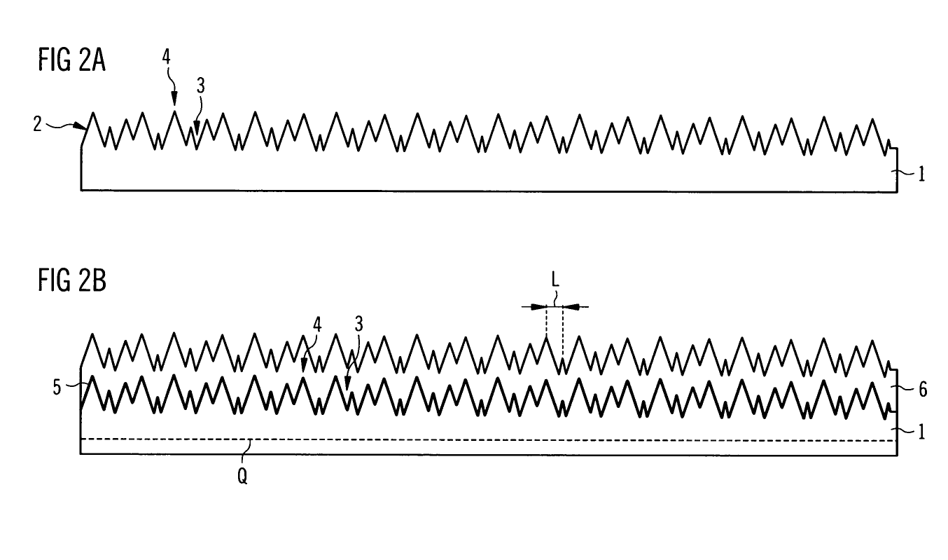

A second exemplary embodiment of a method for producing an optoelectronic semiconductor chip described here is described on the basis of schematic sectional illustrations in conjunction with FIGS. 2A and 2B. As illustrated in FIG. 2A, firstly the growth area 2 of the substrate 1 is roughened.

This is done, for example, by means of anisotropic etching. By way of example, the growth substrate 1 is a GaN substrate, which is roughened by anisotropic etching by means of hot potassium hydroxide—KOH. A crystallographically roughened structured growth area 2 is produced in this way. In this case, the average distance L between two elevations 4 is at most 5 μm, preferably at most 2 μm, particularly preferably at most 0.5 μm.

In this case, the concentration of the potassium hydroxide is preferably between 10% and 50%. The temperature of the potassium hydroxide is preferably between at least 25 degrees Celsius and 95 degrees Celsius. The etching duration is preferably between at least 1 minute and at most one hour. The roughness of the structures produced in this way is preferably greater than 0.1 μm.

As illustrated on the basis of a schematic sectional illustration in FIG. 2B, an active layer sequence 5 is deposited epitaxially onto the structured growth area 2, said active layer sequence following the profile of the structured growth area 2. A p-type contact layer 6 is applied to the active layer sequence 5, said p-type contact layer for example containing p-doped GaN or consisting of the latter.

Besides the advantage of the effectively enlarged area of the active layer sequence, the roughened structure of the growth area 2 also brings about an improved coupling out of light generated in the active layer sequence 5, for example, since the probability of total reflection of the light at one of the outer areas of the optoelectronic semiconductor chip is reduced on account of the rough structure of the active layer sequence 5 and also the rough structure of the surface of the p-type contact layer 6.

Overall, the structuring of the growth area 2 of the growth substrate 1 enlarges the surface of the growth substrate 1 and hence the surface area of the growth area 2. The surface area of the active layer sequence 5 is also enlarged as a result of the enlargement of the growth area 2. In this way, more radiation-generating and/or radiation-detecting area of the active layer sequence 5 is available compared with a growth substrate having a smooth, planar growth area. In this way, a particularly efficient optoelectronic semiconductor chip is produced which, in addition, is particularly cost-effective since the chip area can be reduced compared with conventional optoelectronic semiconductor chips.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

We claim:

1. An optoelectronic semiconductor chip comprising:
a growth substrate with a structured growth area having a multiplicity of elevations and depressions; and
an active layer sequence applied to the growth area.

2. The optoelectronic semiconductor chip as claimed in claim 1, in which the surface area of the active layer sequence is greater than the surface area of the lateral cross-sectional area of the growth substrate.

3. The optoelectronic semiconductor chip as claimed in claim 1, in which electromagnetic radiation is generated or detected during the operation of the optoelectronic semiconductor chip over the entire area of the active layer sequence.

4. The optoelectronic semiconductor chip as claimed in claim 1, in which the growth area is structured regularly.

5. The optoelectronic semiconductor chip as claimed in claim 1, in which the elevations and depressions are arranged periodically.

6. The optoelectronic semiconductor chip as claimed in claim 1, in which the growth area is structured irregularly.

7. The optoelectronic semiconductor chip as claimed in claim 1, in which the growth area is structured irregularly, and in which the surface area of the active layer sequence is greater than the surface area of the lateral cross-sectional area of the growth substrate.

8. The optoelectronic semiconductor chip as claimed in claim 1, in which the elevations and depressions are formed as irregular structures.

9. The optoelectronic semiconductor chip as claimed in claim 1, in which the average distance between two elevations of the structured growth area is at most 2 μm.

10. The optoelectronic semiconductor chip as claimed in claim 1, in which the average distance between two elevations of the structured growth area is at most 1 μm.

11. The optoelectronic semiconductor chip as claimed in claim 1, in which the average distance between two elevations of the structured growth area is at most 0.5 μm.

12. The optoelectronic semiconductor chip as claimed in claim 1, in which the active layer sequence has an average thickness of at most 20 μm.

13. The optoelectronic semiconductor chip as claimed in claim 1, in which the elevations and depressions extend over the entire structured growth area.

14. The optoelectronic semiconductor chip as claimed in claim 1, in which the growth substrate comprises one of the following materials: GaN, SiC, sapphire, InGaN, AlGaN, InAlGaN, ZnO.

15. The optoelectronic semiconductor chip as claimed in claim 1, in which the growth substrate comprises n-doped GaN.

16. The optoelectronic semiconductor chip as claimed in claim 1, in which the elevations and depressions are structured by means of at least one etching process into the growth area.

17. The optoelectronic semiconductor chip as claimed in claim 1, in which the elevations and depressions are produced epitaxially.

18. The optoelectronic semiconductor chip as claimed in claim 1, in which the semiconductor chip having the structured growth area generates or detects more electromagnetic radiation during operation than a corresponding semiconductor chip having a smooth growth area.

19. The optoelectronic semiconductor chip as claimed in claim 1, in which the semiconductor chip having the structured growth area generates or detects electromagnetic radiation having a higher radiation density during operation than a corresponding semiconductor chip having a smooth growth area which has the same lateral cross-sectional area as the semiconductor chip having the structured growth area.
